(19) United States
(12) Patent Application Publication
(10) Pub. No.: US 2006/0103860 A1
(43) Pub. Date: May 18, 2006

(54) Reflective additive-primary color generators

(76) Inventor: R. Sloan Wilson, New Haven, CT (US)

Correspondence Address: SLOAN WILSON, 1140 Chapel St., New Haven, CT, 06511, US

(21) Appl. No.: 10/987,781

(22) Filed: Nov. 12, 2004

(51) Int. Cl. G03F 3/08

(52) U.S. Cl. 358/1.9; 358/518

(57) ABSTRACT

This invention underlies a set of 3-dimensional art objects which may also find utility in the studies of vision science, geometry and physics. The apparent luminance of reflected colors is altered by the introduction of zero (or low) light intervals. In the first species, the intervals of darkness lie between colored regions in a static manner. In the second species, a time-period of darkness is caused by shadows. When viewed under incidental white light, the objects (except for three alternates described in section II) exhibit additive primaries by reflection to stimulate sensations of secondary colors—magenta, cyan, and yellow—and tertiary colors

### FIELD OF INVENTION

This invention relates to additive color perception and the luminosity finction involved in color perception. Geometry and inertia play integral roles in the way in which secondary and tertiary colors, including magenta, yellow and cyan, are additively generated from three pigment primaries of red, green, and blue, and intervals of zero light. Two species of the invention, each with subspecies, are presented. The first is essentially static and involves ‘pointillistic’ color-mixing on an openwork structure. The second is a spinning top with an intriguing kinetic function driving kinematic color effects.

### BACKGROUND

Background for the Openwork Generators

Generally recognized are two color-mixing systems, additive and subtractive, each with very specific primary colors that afford efficient means of generating virtually all the colors of the visible spectrum. The two systems come together as inversely related sets of three primaries, such that the primaries of one system are the secondary colors of the other. It is ordinarily assumed that reflected color operates under subtractive rules, and that emitted color operates under additive rules. One cannot make a luminous yellow from even the brightest red and green pigments by mixing the colored particles so close together that they absorb or filter each other's reflected colors. Stirring paints or overlaying transparent inks allows for cancellations of color and yields a darker total reflection. In the case of mixing green and red pigments, a rust color is the result. A pointillistic approach in which dots of red and green pigments are placed side by side produces a brighter yellow, but the low level of reflected light still diminishes the effect.

Current theories of vision broadly divide our perception of luminosity and color into two different retinal responses—receptor cells that are sensitive to light and dark, but not to color (rods), parallel color-sensitive receptors (cones). Before responses are sent to the brain, a network of ganglion cells channels these receptors' input. Ganglion cells possess concentric zones of sensitivity, called receptive fields, which may cover relatively large regions (1 mm) of receptor cell signals. Variables in the light stimulus, such as intensity, size, and location of the stimulus within the cell's receptive field, determine whether the cell is excited or inhibited. Ganglion cells respond weakly when input from their connected receptors covers the ganglion's entire receptive field, but strongly when the input is localized to a specific region in the field.¹ The color response is apparently also of a lower resolution than the light/dark response.² When colored dots (as in a color halftone photograph) appear smaller than the retina's receptive fields, the eye can no longer distinguish the boundaries of the colors, so they are merged.³ An example given by Livingstone, (Vision and Art, 2002), shows a tightly packed array of non-overlapping blue and yellow pigment dots, which, from a distance appears gray. White would be the result if blue and yellow lights were used, but the example is reflective and, as the researcher explains, the luminosity is lower.
¹Dowling, The Retina, 1987; Livingstone, Vision and Art, 2002; Gergenfurtener and Sharpe, Color Vision, 1999; see chapter 7 of Dowling for general information on dark adaptation and cellular dark-responses.

²Livingstone, Vision and Art, 2002

³ibid.

The size of colored dots in an array, with respect to the size of receptor fields of the retina, must certainly be part of the retina's interpretation of the overall color of the array, but surely, the role of the lens and pupil in focusing the diffusion is important. An array of tightly-packed colored dots sheds more light than an array of dots spaced on a black field. If the pupil contracts under the brighter condition, the amount of radiation entering the eye from any given point will be smaller and, though there are more dots in the tightly packed array, the smaller quantity of radiation from each point means there will be less energy from any given colored dot.

Under darker conditions the total reflectance decreases and the pupil may dilate. In this case, a larger quantity of radiation from any given point will be selected by the aperture and there will be more energy from each dot. This arrangement may evoke stronger signals from the ganglion cells. If this is true, then colors do not just seem stronger with contrast, but actually are stronger.

Livingstone (Vision and Art, 2002), references numerous artists in her assessment of pointillist color, and Rosotti, (Colour, 1983), writes “ . . . optical mixing need not yield only white; a mosaic of red and green gives a vibrant yellow. Such effects have been much exploited in textile design . . . ” Though textile designers and artists have certainly employed additive color-mixing, either consciously or unconsciously, I have not found a three-dimensional implementation similar to the one outlined in this specification.

Color-coding is often used to clarify geometric structures, and frequently appears in text-books and computer simulations. The intention, however, is not to generate new color. As well, many color models employ three virtual dimensions for simplifying the representation of colors, and are particularly useful as interfaces for computer users. These color-space models vary both the hue intensity, (or saturation), and the light/dark values by positioning the primaries, plus white and black, at different points in virtual 3-D. A 3-D matrix is convenient since the primaries and their ratios can be represented as one plane repeated as a stack of planes extending along a third axis between black and white. Two dimensional slices from the stack are then consulted and a point on the slice is specified.

There is also a product called Color-Cube, (U.S. Pat. No. 05,634,795, Davies, 1997), which seeks to show in 3-dimensions, the virtual color-space as an array of smaller real cubes, each small cube being painted with a unique color matched to one of the numerous emissive selections. The intention of the Color Cube, however, is not to actually mix additive colors.

Transparent colored polyhedra, such as decorative containers, are not uncommon. For a polyhedron with transparent additive-color faces (red, green, and blue), the faces will function subtractively and absorb color from distal faces. These cancellations of color weaken the result in the same way stirring additive primaries does. With transparent subtractive colored faces (magenta, yellow, and cyan), the faces of the polyhedra will also function subtractively, but to positive effect. A cyan face (cyan stimulates our blue and green receptors) will absorb, or filter, the red from a yellow face behind it (yellow stimulates our red and green receptors). The perceived color will be the bright yellow-green of the additive system.

Background for the Kinetic Generators

A yellow-orange can be perceived from a rapid succession of red and green paint swatches, (as on a spinning disk). This is a purely additive process because the two colors are coming to the eye unfiltered and at different times—the pigments have no opportunity to cancel each other. Newton used spinning discs sectioned in various colors to determine the seven primaries of his system, and one can still buy a Newton color wheel from any number of educational-instrument outlets. Spinning color discs like this work by rapid sequencing of color through two dimensions, which is similar to a simultaneous diffusion, but one that must take advantage of the cone response time.

In the literature are found suggestions of using rotational means to make secondary color from pairs of red, green, or blue. There are science projects instructing students to color half a disc in one primary and the other half in another primary to arrive at a single secondary color, but descriptions of reflected-light additive-primary color wheel experiments such as these, at least those found by this author, do not accurately describe the primaries, (i.e. range of wavelengths or nature of pigments), so it is difficult to determine the quality of the complements produced. Furthermore, they operate by rotation through only two dimensions, and do not incorporate all three primaries with a dark, or zero-light function.

There is an antique pump-action top still in production that uses three, geared, tricolor discs to effect changing secondary color, but, as many old toys, the primaries are red, yellow, and blue with the red and blue of hues associated with the subtractive primaries and not the additive primaries. It is an interesting device, and utilizes a black field for part of its effect, but the use of subtractive primaries for optical mixing is the reason why it is not as effective as the one outlined in this application. (The device doesn't make a vibrant green and can be improved by using additive primaries). There is another spinning color device, (U.S. Pat. No. 2,631,405) that in principle sounds similar to the one presented here, but, like the previous example, because it employs mostly subtractive primaries for an additive process, and because its structure limits the coloration schemes to bipolarization, can only be considered tangential. None of the above examples operate by means of the disclosed invention. In terms of mechanics, the most relevant item is the flip-over top (U.S. Pat. No. 01,780,547, Alland, 1930, and an improvement, British patent 656540, Christie and Jay Ltd., 1951).

Other items to reference include U.S. Pat. No. 02,184,125, Patterson, 1939; U.S. Pat. No. 03,474,546, Wedlake, 1969; U.S. Pat. No. 05,310,183, Glikman, 1994; U.S. Pat. No. 05,634,795, Davies, 1997; U.S. Pat. No. 06,050,566, Shameson, 1998; U.S. Pat. No. 02,583,275, Olson, 1949; U.S. Pat. No. 02,332,507, Dailey, 1943; U.S. Pat. No. 00,547,764, Boyum, 1895; and the work of artists Lucas Samaras and Sol LeWitt.

### BRIEF DESCRIPTION OF THE INVENTION

The invention underlies a set of 3-dimensional art objects which may also find utility in the studies of vision science, geometry and physics. In all cases (except for two variants mentioned in the last paragraph of section I, titled Openwork Color Generator) the apparent luminance of reflected colors is altered by the introduction of zero (or low) light intervals. In the first species described, the intervals of darkness lie between colored regions in a static manner. In the second species, a time-period of darkness is caused by shadows. When viewed under incidental white light, the objects (except for three comparative studies described in section II, titled Openwork White Generator) exhibit additive primaries by reflection to stimulate sensations of secondary colors—magenta, cyan, and yellow—and tertiary colors. Again, the primaries exhibited from these objects are those primary colors associated with the additive system, (namely blue, green, red), but are reflective, not illuminants. The objects may be viewed together or independently. The primaries, blue, green, and red, labelled B, G, or R in the figures and text, are detailed at the end of the specification.

### BRIEF DESCRIPTION OF THE DRAWINGS

FIG. 1 shows one manifestation of the invention described in the first subsection titled ‘Openwork Color Generator’.

FIG. 2 shows one color break for one manifestation of the invention described in the first subsection as ‘Openwork Color Generator’.

FIG. 3 shows a third manifestation of the invention described in the first subsection as an ‘Openwork White Generator’.

FIG. 4 shows the first view of a fourth manifestation of the invention, a spinning top, described in the third subsection tided ‘Kinetic Color Generator.’ This figure shows the parts and general proportion of the top.

FIG. 5 shows a sectional view of the spinning top illustrated in FIG. 4 and the inclination produced by the addition of one weight [4].

FIGS. 6 through 9 show views of the spinning top illustrated in FIG. 4 as it proceeds through one period of rotation.

### DETAILED DESCRIPTION OF THE INVENTION

This application claims the benefit of U.S. Provisional Application No. 60/519720, filed Nov. 12, 2003 and U.S. Provisional Application No. 60/520873, filed Nov. 18, 2003. (35 USC 119 (e)).

I. Openwork Color Generator

An arrangement of a set of sheets made from openwork material, such as but not limited to wirecloth, is pigmented so that one of each of the additive primaries is clearly visible from a plurality of domains of the openwork surface, and the plurality of domains from which each primary is visible being about ⅓ the whole of this surface. For asymmetric forms, the size of the domains covered by a primary may change with respect to the asymmetry of the arrangement. For instance if the cube in FIG. 2 were increased in the y dimension, the colors occupying the faces extended in y might also increase.

The sheets are arranged so that an observer will see pairs of sheets superposed and pairs from the group of the primaries at any viewing angle, except where an opaque presentation base or support for the sheets may naturally obscure viewing. The members of the set of sheets are joined by such means as, but not limited to, hinges, rotational axles, pegs, fusing the material, knotting, twisting, bending.

The arrangement of sheets is positioned against a field of zero, or near zero luminance (such as black velvet and which may also include darkening the room in which the arrangement is presented), and illuminated for viewing with one or more incidental white light sources. A spotlight, sunlight, or a bright halogen light work well—a second or third light from different angles will help eliminate shadows. (In this case shadows are an unintentional interference).

The reflected colors of two overlapping regions stimulate responses of secondary and tertiary colors. At an appreciable distance, an observer in motion with respect to the arrangement of the sheets will naturally experience parallax between the sheets' nearer and firther regions. A walk around the arrangement prompts an observer to discover that the same domain of any one primary color contributes, by superposition over one or the other primary domains behind it, to the product of two different secondary colors. These colors alternate as the observer moves around the arrangement. To effect the same alternations, the arrangement itself can also be made to turn by a variety of means.

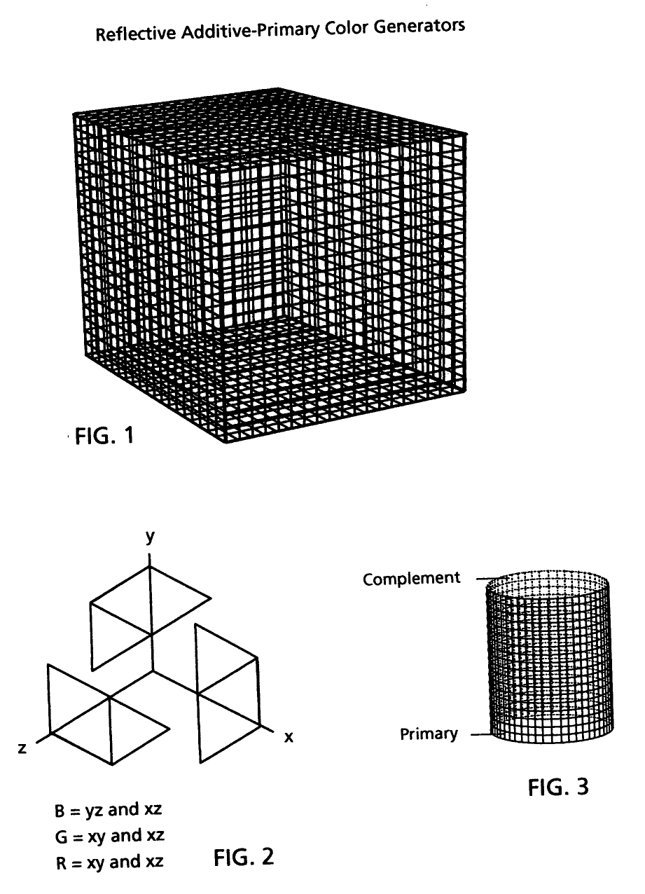

The parallax is most dramatic when the sheets are arranged as planes meeting at 90° to one another. An observer moving around a set of planes constructed as the cube in FIG. 1 with the primaries arranged as in FIG. 2 will discover different ratios of the three primaries [B, G, R]. The density of one color arriving at the retina from the inside of a posterior surface, increases as the viewing angle with respect to that surface's plane approaches 0°. The increased density of this colored light passes through the open regions of the face nearest the viewer, which is 90° to the former. This allows for different ratios of the two primaries. The varying ratios of two different primaries produce variants of the secondary colors—the tertiaries. If the arrangement forms a hexahedron, there are five possibilities for positioning the colors, one of which was shown in the provisional application. If the three primaries are arranged so that identical primaries appear on adjacent faces, then a view along a line joining two corners shows the circular sequence of the spectrum [FIG 2].

The shadows cast by the openwork nearest the source or sources of light effect the amount of color visible from other domains. If the openwork's apertures are proportionally small with respect to its material surface area, allowing less light to pass, the amount of color visible from domains behind it diminishes (unless independently illuminated). Thus the openwork of the sheets must be consistent for an effect that works similarly from all angles of viewing. A wire diameter of about 12-15% of the open width of a unit of wire cloth works well in the case exhibited in FIG. 1, however the openwork may be inconsistent to produce variations of the color generating effects.

Ultimately it is the separation of the primaries allowed by the openwork which plays a crucial role in the sensation of clean secondary colors from pigments of these additive primaries. Sheets may be of unit value of the openwork, i.e. polygons or circles. The lattices may also be applied as opaque inks or paint to a clear substrate. While technically not as effective as the above description, a cube with transparent lattices of the primaries show a pleasing effect. Derivatives of the invention might include lattices of emissive light. Three primaries of laser light could be reflected as a mesh along a mirrored framework to reflect their light in a vapor or gas cloud.

II. Openwork White Generator

FIG. 3 shows a comparative study—the object constructed as above, but reflecting one additive primary (blue, green, or red) and its secondary complement (yellow, magenta, or cyan) will produce white against a black ground.

III. Kinetic Color Generator

The spinning top illustrated in FIG. 5 has a rigid disc [2] fixed between the spheroid base [1] and the shaft or spindle [3]. The disc has three functions: a) it serves as a platform for pigment versions of the three additive primaries, red [R], green [G], and blue [B], which appear as three equally-sized sectors of the disc; b) the disc acts as a stabilizer limiting the inclination of the top's axis; c) it provides a convenient place for a small repositionable weight or weights [4] to be applied and relocate the center of mass of the top. Once the top is spinning, the primary function of the shaft [3] is to provide shadows and break the sequence of colors. It can be white, black, or a vertical continuation of the primaries appearing on the disc, but a non-intrusive color, such as natural wood is best. A clear matte finish shaft for plastic versions of the top is interesting but not as effective as opaque variety. The base of the spinning top plays little role in the color effects and may be any color that does not cancel the effects of the colors on the disc. For variations and nuance of colors, the sectors [R], [G], [B] in FIG. 4 may be increased or decreased slightly. U.S. Provisional Application No. 60/519720 stated the proportions of the top and they are essentially the same as specified in this disclosure. The general proportions to obtain the desired motion can be inferred from the example provided here, which assumes a solid hardwood base [1] of 31.75 mm diameter by 23.8125 mm height, a disk [2] of similar solid material (such as basswood ply) in the range of 47.5 mm to 54 mm in diameter by 1.6 to 2 mm thick, and a shaft [3] of similar solid material with a length ranging from about 25 mm to 32 mm, with diameter 6.35 mm

FIG. 5 shows one clip weight [4] applied to the disc, and the center of mass shifted slightly from a location [M1] above the base's radial center [Q], to a point [M2] in the direction of the weight. When spun, the top inclines and turns about a new axis between the radial center [Q] and the center of mass [M2] in such way as to create, at various locations in the sweep of the top's motion, different ratios of the three primaries and the zero color factor. The locations of the primaries on the disc are referenced as letters [R], [G], [B].

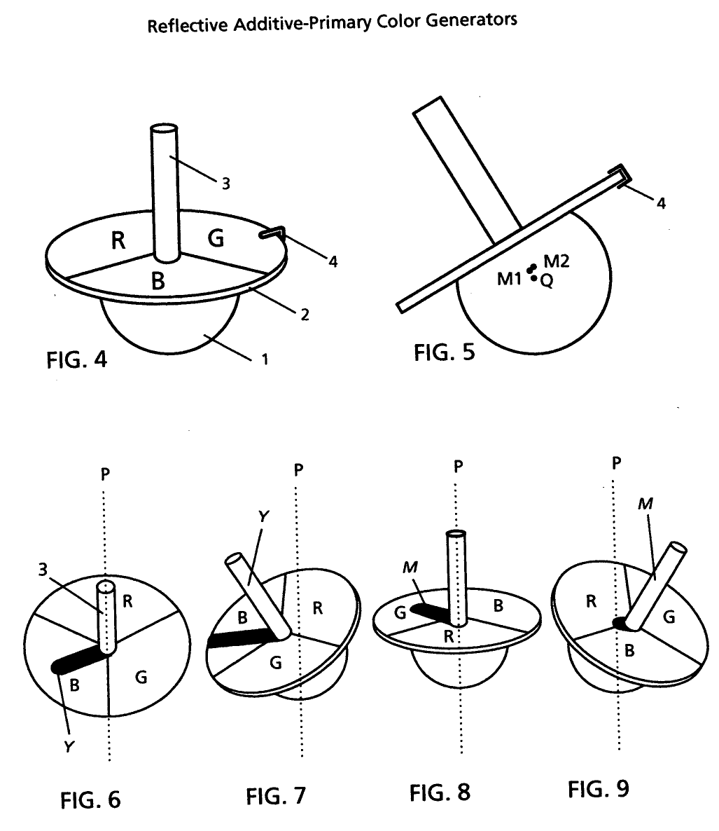

FIGS. 6 through 9 show one type of rotation the top will make, and represent quarter-period positions of the top over one period. The locations of the primaries on the disc as the top turns around the vertical axis P [P] are referenced as letters [R], [G], [B]. When the top is set in motion near a lamp located forty-five degrees to P, an observer also forty-five degrees to axis P but ninety degrees to the lamp, will see a cone of ellipses formed by the moving disc, and a cone formed by the shaft [3]. The observer will also see several new regions of color other than the primaries. There is an upper region of color occurring toward the back of the disc's sweep, a lower region of color occurring toward the front of the disc's sweep, two colored regions in the shadows cast on the disc by the shaft, and two colored regions at the extreme positions of the shaft itself. The regions of secondary colors related to the shaft and its shadows, are indicated in italics [Y] and [K]. The two regions of color at the disc's upper and lower extremes are not referenced in the figures but can be inferred by examining the disc's orientation across the horizontal dimension and summing the occurance of primary colors for a point in the disc's sweep but relative to the top's motion. (the figures are aligned horizontally along the focus of the cycle). In FIGS. 6 through 9, the colors would be cyan in the disc's lower region and red in the upper. Used under ordinary incidental white light, but preferably against a dark field under an incandescent spotlight (with a bit warmer hue than sunlight and which casts crisp shadows), the range of colors produced includes magentas, violets, blues, cyans, greens, yellows, oranges, and reds.

Variations in the degree of inclination, the period, or periods, between maximal and minimal inclination, and whether or not the top spins around its geometric axis (axis of structural symmetry through the shaft) during its rotation around axis P, may arise from the nature of the materials used for construction. The top made from hardwood and ply, (0.00065 grams per cubic millimeter), tends to either change angle and color in regular intervals (rocking), or stabilize at a constant angle until a disturbance interrupts it. The stabilized top constructed from lighter materials generally does not also spin around its own axis of symmetry during the rotation around P, except when there is a change in its inclination due to such a disturbance or change in equilibrium. In the steady state the top does not exhibit a classic precession and therefore exhibits no shifts in the observed secondary colors. The arc of the base allows smooth transitions between inclination changes but also allows the top to travel laterally across the surface upon which it spins, so a dish is helpful to contain it.

The same device made from a heavier wood or uniform material like acrylic (0.00118 grams per cubic millimeter), can be balanced to produce a progressive precession which gradually falls to about 30°, or even 40° from vertical. These tops also spin around their own axes during precession.

Ideally the tops might be made of a plastic with the same density of the hardwood, providing consistency in manufacturing, but the irregularities of wood make each one slightly unique.

The top should be spun under adequate illumination (but preferably not fluorescent), and while not consequential to the effectiveness of the device, spinning on a dark surface enhances one's perception of the colors. To best see the colors, the top should be spun very fast. In bright sunlight a fast spinning speed is essential. As an alternative to the repositionable weight [4], a bit of wax can also be placed under the disc to alter the resulting geometric image and color effects. The top can be spun with a launcher

Wavelengths of the Reflected Primaries

The additive primary red [R] indicated in this specification and in the figures reflects wavelengths 570-700 nm with peak values starting near 620 nm. The additive primary green [G] indicated in this specification and the figures reflects wavelengths 500-650 nm with peak values near 550 nm. The additive primary blue [B] indicated in this specification and the figures reflects wavelengths 400-700 nm with peak values near 440 nm. An alternative blue [B] reflects wavelengths 400-700 nm with two peak values, one near 440 nm and the second near 510 (cobalt has a third curve near 700 but it is hard to notice with the naked eye).

Pigments and Pigment Compounds Used for the Invention

The primaries red, green, and blue, can be made from a number of fundamental coloring agents. The author has obtained them using the following pigments: Ultramarine (PB 29); Cobalt blue (PB 28); Cadmium reds; Cadmium oranges; Cadmium yellows; Naphthol red light (PR 112); Irgazine red; Irgazine orange; Arylide yellow (PY 73 GX); Arylide yellow (PY 3); Phthalocyanine green (PG 7); Zinc white (PW); Titanium white (PW 6); Aluminum oxide.

Alteration of Values

The values of all three primaries, red, green, and blue, indicated above, may vary to some degree, but it is important their relationship be consonant. The naturally dark blue pigments used to make the primary blue, in all cases of the specified invention, have been modified with white in order to bring that value within range of the red and green, such that on a value scale from 1 to 10, where red is near 6, and green near 5, then blue will be near 4. Likewise, if the values for red and green are near 7 and 6, then blue would be near 5.

I claim:

1-7. (canceled)

8. A tri-primary, additive color-mixing process producing a range of colors including magenta, cyan and yellow, wherein intervals of darkness and diffuse reflections from a minimum of three primary-color domains, each domain being red, green, or blue, and located at the surface, or surfaces, of a three-dimensional structure, are reintegrated to stimulate a plurality of secondary colors in an observer by means of changes in orientation between the observer and the structure.

9. The color-mixing process of claim 8 wherein said red has peak wavelengths in the neighborhood of 620-700 nm, said green has peak wavelengths in the neighborhood of 550 nm, and said blue has peak wavelengths in the neighborhood of 440-450 nm.

10. The color-mixing process of claim 8 wherein said structure is transparent and said three primary-color domains appear as openwork fixed to the surface of said structure.

11. The color-mixing process of claim 8 wherein said structure is an openwork structure.

12. A top with a curved base and a shaft for spinning the top, wherein a disc of rigid material is fixed orthogonally between said base and said shaft, said top having a center of mass located in a zone slightly above the radius of arc, or radial center, of said base.

13. The top of claim 12 wherin a small repositionable weight is fastened to the perimeter of said disc by means from the set of fasteners including a clip, an adherent.

14. The color-mixing process of claim 8 wherein said structure is a top comprised of, a) a curved base, b) an opaque shaft for spinning the top, c) an opaque, rigid disc fixed orthogonally between said base and said shaft, d) a center of mass located in a zone slightly above the radius of arc, or radial center, of said base, and wherein said three primary-color domains appear at the surface of said disc.

15. The color-mixing process of claim 8 wherein said structure is constructed as a top comprised of, a) a curved base, b) an opaque shaft for spinning the top, c) an opaque, rigid disc fixed orthogonally between said base and said shaft, d) a center of mass located in a zone slightly above the radius of arc, or radial center, of said base, e) a small repositionable weight fastened to the perimeter of said disc by means from the set of fasteners including a clip and an adherent and wherein said three primary-color domains appear at the surface of said disc.

16. The color-mixing process of claim 8 wherein said structure is a top comprised of, a) a curved base, b) an opaque shaft for spinning the top, c) an opaque, rigid disc fixed orthogonally between said base and said shaft, d) a center of mass located in a zone slightly above the radius of arc, or radial center, of said base, and wherein said three primary-color domains appear at the surface of said disc and the field surrounding said top is low or near zero.

17. The color-mixing process of claim 8 wherein said structure is constructed as a top comprised of, a) a curved base, b) an opaque shaft for spinning the top, c) an opaque, rigid disc fixed orthogonally between said base and said shaft, d) a center of mass located in a zone slightly above the radius of arc, or radial center, of said base, e) a small repositionable weight fastened to the perimeter of said disc by means firom the set of fasteners including a clip and an adherent, and wherein said three primary-color domains appear at the surface of said disc and the reflectance in the field surrounding said top is low or near zero.
